(19) United States
(12) Patent Application Publication
(10) Pub. No.: US 2026/0068112 A1
(43) Pub. Date: Mar. 5, 2026

(54) LOCALIZED RADIATION SHIELDING FOR SPACE APPLICATIONS

(71) Applicant: Raytheon Company, Tewksbury, MA (US)

(72) Inventors: Paola V. Lopez, Santa Fe Springs, CA (US); Charles Chu, Temple City, CA (US); Kevin A. Miyamoto, Camarillo, CA (US); Rosalio S. Vidaurri, Los Angeles, CA (US); Keith R. Burrell, Rancho Palos Verdes, CA (US); Andrew J. Bristol, Los Angeles, CA (US)

(21) Appl. No.: 18/819,561

(22) Filed: Aug. 29, 2024

(51) Int. Cl. H05K 9/00; B64G 1/54; H05K 1/18; H05K 7/14

(52) U.S. Cl. CPC H05K 9/0007; B64G 1/546; H05K 1/181; H05K 7/1427; H05K 2201/10742

(57) ABSTRACT

A radiation shielding assembly for an electronic component is provided. The assembly includes a printed wiring board and a radiation shield having first and second covers on the printed wiring board. The first cover has first cover walls and the second cover has second cover walls. The first cover walls define a housing and have first cover cavities. The second cover walls have second cover thru passages. The assembly has the electronic component disposed on the printed wiring board and within the housing. The electronic component has a perimeter on the printed wiring board where the printed wiring board has passages at the electronic component perimeter. The first walls are located at the electronic component perimeter to enclose the electronic component.

### TECHNICAL FIELD

Examples relate to radiation shields for spacecraft applications and more specifically to radiation shields for electronic components in a spacecraft.

### BACKGROUND

Spacecraft require electronic components in order to properly function. Electronic components can be mounted on printed wiring boards disposed within the spacecraft. However, by virtue of being in outer space and in closer proximity to the sun, the electronic components are subject to ionic radiation.

Types of ionic radiation include Total Ionizing Dose (TID), charge build-up, displacement damage, and single-event effects.

TID can occur when ionizing radiation is absorbed by the spacecraft over time. Charge build-up can occur when energetic electrons and protons penetrate a Faraday cage of the spacecraft. This can lead to Internal Electrostatic Discharge. Displacement damage can occur when radiation causes physical defects in the material of the spacecraft. These defects can lead to degradation of electrical properties of the spacecraft material. Single-event effects can occur when an energetic particle strikes a sensitive area of the electronic component. Individually, all of these types of ionic radiation can lead to premature failure of electronic components, thereby jeopardizing the mission of the spacecraft.

### BRIEF DESCRIPTION OF DRAWINGS

FIGS. 1A and 1B show carriers that hold electronic components within a spacecraft.

FIG. 2 illustrates a spacecraft on which examples described herein may be used.

FIG. 3 shows a radiation shielding assembly that can be used with the spacecraft of FIG. 2.

FIG. 4 illustrates a perimeter of an electronic component of the radiation shielding assembly of FIG. 3.

FIG. 5 is an exploded view of the radiation shielding assembly of FIG. 3.

FIG. 6 shows walls of a cover of the radiation shielding assembly of FIG. 3.

FIG. 7 illustrates the application of the radiation shielding assembly of FIG. 3 to multiple electronic components.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims.

Examples relate to an assembly that provides radiation shielding for an electronic component in a spacecraft. The assembly can include a radiation shield having an upper cover and a lower cover where one of the radiation shield upper cover and the radiation shield lower cover can define a housing within which an electronic component can be disposed. The electronic component can be mounted on a printed wiring board where a perimeter surrounds the electronic component on the printed wiring board. Either the radiation shield upper cover or the radiation shield lower cover can be disposed within the electronic component perimeter. The radiation shield upper cover can include a lip that extends around a periphery of the radiation shield upper cover. Similarly, the radiation shield lower cover can include a lip that extends around a periphery of the radiation shield lower cover. When the radiation shield encloses the electronic component, the upper cover lip can align with the lower cover lip.

The radiation shield upper cover can include first and second walls. The upper cover first and second walls can define the housing within which the electronic component can reside when the radiation shield upper cover is disposed at the electronic component perimeter. The radiation shield lower cover can also include first and second walls. In examples when the radiation shield lower cover is disposed in the electronic component perimeter, the lower cover first and second walls can define the housing within which the electronic component can reside.

Each of the upper cover first and second walls and the lower cover first and second walls can include passages configured to receive fasteners that can couple the radiation shield upper cover with the radiation shield lower cover.

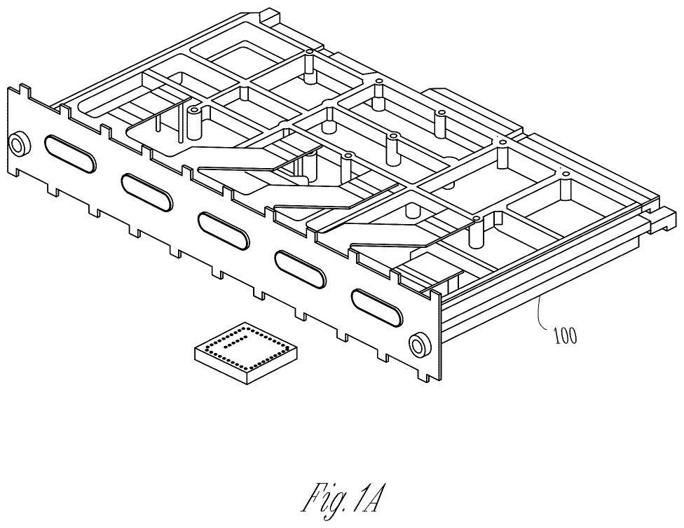

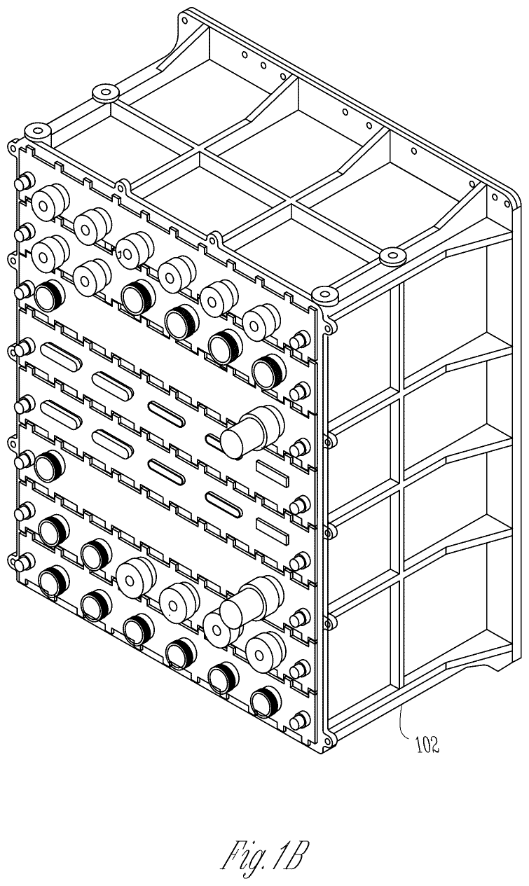

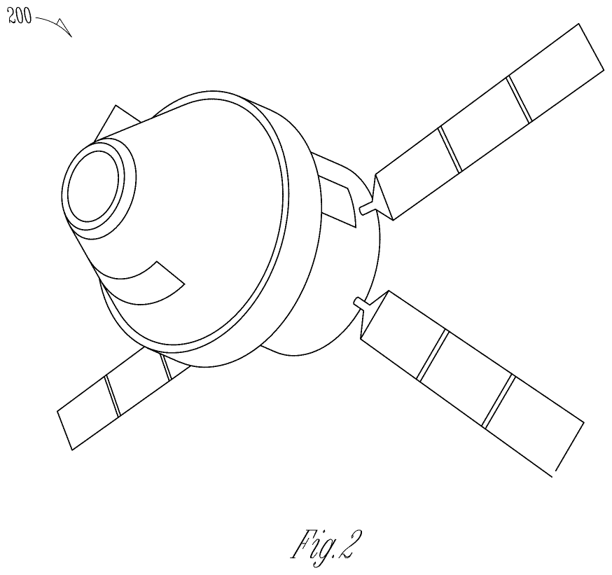

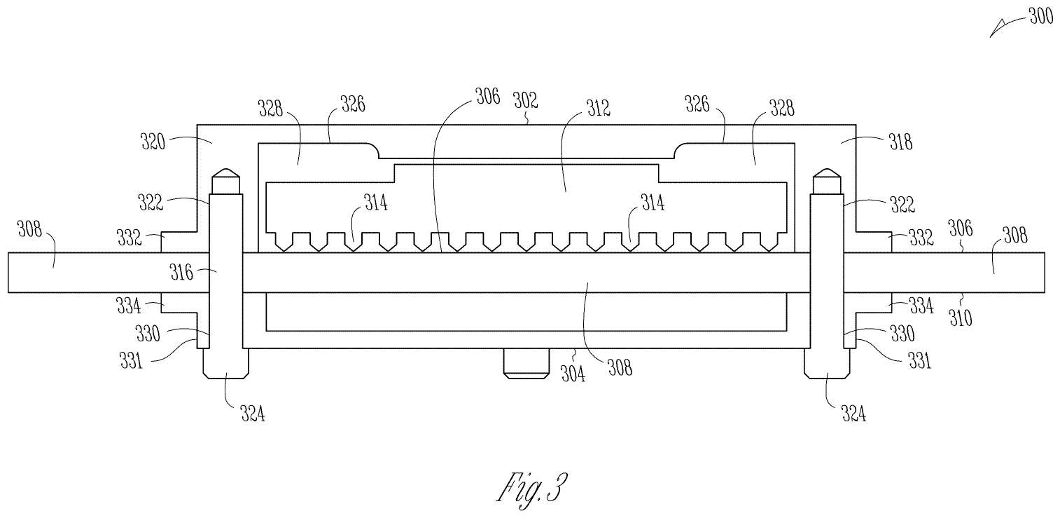

Now referring to FIGS. 1A and 1B, carriers 100 and 102 that typically hold electronic components within a spacecraft 200 (FIG. 2) are shown. Specifically, electronic components can be placed on the carrier 100 and, in some instances, the carrier 100 can be placed inside of the carrier 102. However, radiation can enter the carrier 100 and potentially cause the problems discussed above. In order to address these problems, a radiation shielding assembly 300 that can be used with the spacecraft 200 can include an upper cover 302 and a lower cover 304 opposite the upper cover 302. The upper cover 302 in conjunction with the lower cover 304 can define a radiation shield, as shown with reference to FIG. 3. The upper cover 302 can be on a first side 306 of a printed wiring board 308. The lower cover 304 can be on a second side 310 of the printed wiring board 308.

The printed wiring board 308 can include a substrate that can support and connect electronic components, such as an electronic component 312, using conductive pathways that can be printed or etched onto a non-conductive substrate. The substrate of the printed wiring board 308 can be formed from phenolic paper, epoxy glass, polymide, or the like. In addition, the substrate of the printed wiring board 308 can be formed from a material providing any suitable mechanical strength and electrical insulation suitable for spacecraft applications.

The electronic component 312 can be an active component, a passive component, or specialized component. Examples of active components can include a transistor, a diode, an integrated circuit, a microprocessor, or an operational amplifier. Examples of passive components can include a resistor, a capacitor, an inductor, a transformer, or a potentiometer. Examples of a specialized component can include a Zener diode or a varicap diode. While active, passive, and specialized components are described herein, the electronic component 312 is not restricted to the components discussed herein. For example, the electronic component 312 can be an ideal diode controller, a light-to-frequency converter, an ultra-low voltage adjustable shunt regulator, or an Anderson powerpole connector.

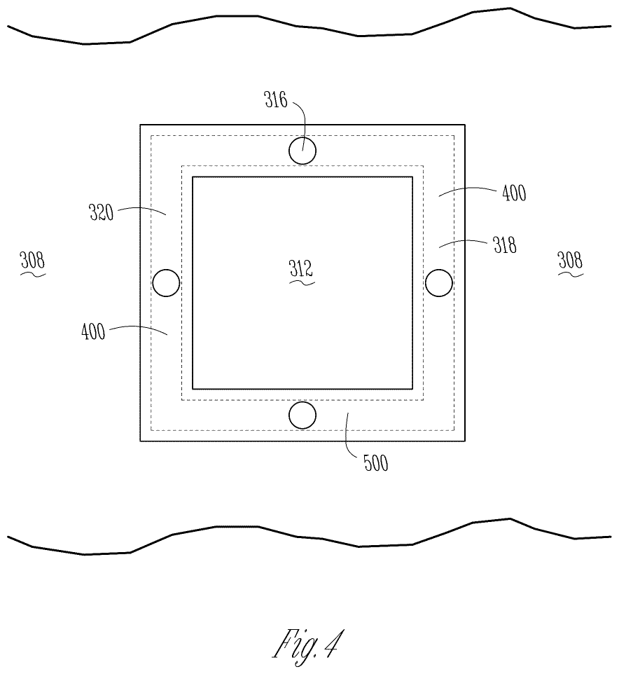

The electronic component 312 can be in the form of a plastic ball grid array having a ball grid array 314 that contacts the printed wiring board first side 306. In order to attach the ball grid array 314 to the printed wiring board 308, the ball grid array 314 can be aligned with pads on the printed wiring board 308 and then attached to the printed wiring board 308 using stencil printing and solder paste. The formed assembly between the printed wiring board 308 and the ball grid array 314 can then be subjected to a reflow process where the printed wiring board 308 is subjected to a heating process. In order to facilitate the reflow process, the electronic component 312 can define a perimeter 400 as shown with respect to FIG. 4. The printed wiring board 308 can include printed wiring board passages 316 that are disposed at the electronic component perimeter 400, as shown with respect to FIG. 4.

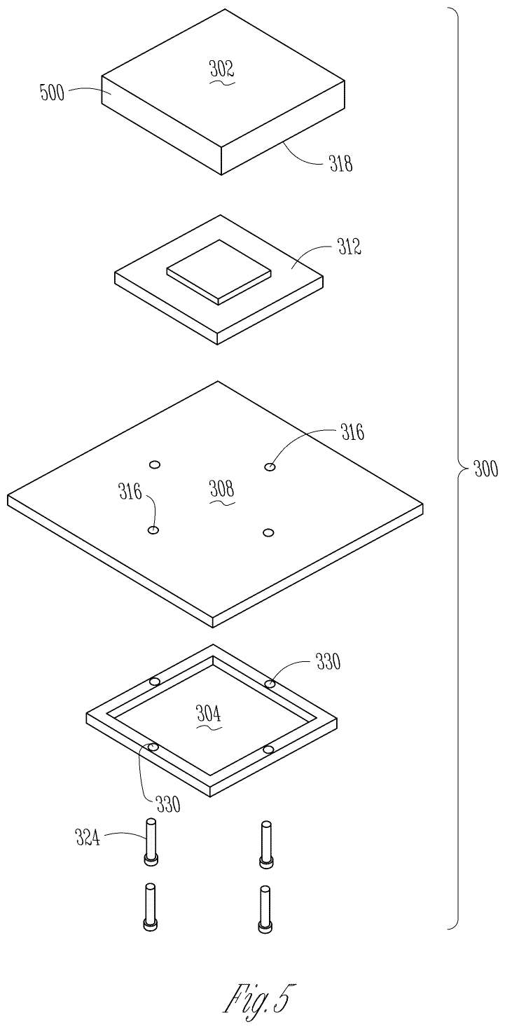

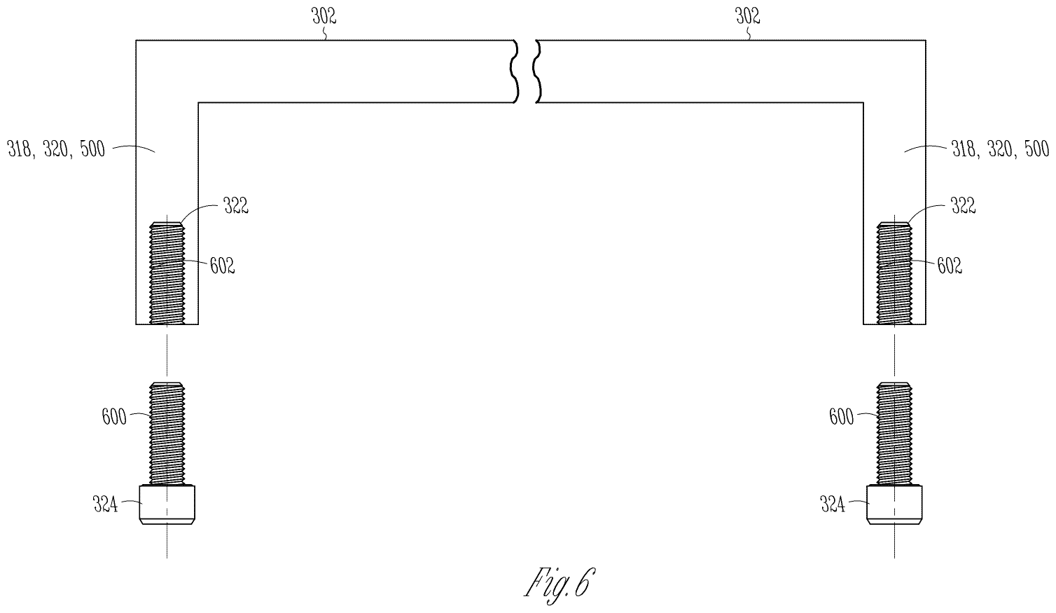

The upper cover 302 can include upper cover walls 318, 320, and 500 (FIG. 5) that can each define cavities 322. The radiation shielding assembly 300 can include a plurality of fasteners 324 where the cavities 322 can be configured to receive the fasteners 324. In some examples, the fasteners 324 can be threaded fasteners and can include threads 600 as shown with respect to FIG. 6. Here, the cavities 322 can include threads 602 that can complement and mate with the fastener threads 600. Thus, when the fasteners 324 are inserted into the cavities 322, the fastener threads 600 in conjunction with the cavity threads 602 can secure the fasteners 324 within the cavities 322 and seal the upper cover 302 against the printed wiring board first side 306 and the lower cover 304 against the printed wiring board second side 310 thereby sealing the upper cover 302 and the lower cover 304 against the printed wiring board 308.

Returning attention to FIG. 3, the upper cover walls 318, 320, and 500 along with an upper cover surface 326 can define a housing 328 within which the electronic component 312 can disposed. The housing 328 can enclose the electronic component 312 against the printed wiring board first side 306, as shown with respect to FIG. 3. Here, the upper cover walls 318, 320, and 500 can be disposed at the electronic component perimeter 400 (FIG. 4).

The lower cover 304 can include thru passages 330 through which the fasteners 324 can pass. The lower cover 304 can include a plurality of walls 331 where the thru passages 330 can be disposed within the walls 331. In particular, the fasteners 324 can pass completely through the lower cover thru passages 330 and engage with the cavities 322. The printed wiring board passages 316 can align with the cavity 322 and the lower cavity thru passages 330 such that the fasteners 334 can pass completely through the lower cover 304 and completely through the printed wiring board passages 316 and into the cavity 322. The upper cover 302, the lower cover 304, the upper cover walls 318, 320, and 500 and the lower cover walls 331 can be formed from any high-density material. Examples of high-density materials can include copper and plastic.

As shown with reference to FIG. 5, the lower cover 304 can include four lower cavity thru passages 330 that can align with four printed wiring board passages 316 and with four cavities 322 (not shown) to allow the passage of four of the fasteners 324. However, examples envision any number of lower cavity thru passages 330, any number of printed wiring board passages 316, any number of cavities 322, and any number of fasteners 334.

The upper cover 302 in combination with the lower cover 304 can function to minimize the penetration of radiation into the electronic component 312. In particular, the upper cover 302 in combination with the lower cover 304 can encapsulate the electronic component 312, thereby protecting the electronic component 312 from radiation and mitigating the problems discussed above.

The upper cover 302 can also include a lip 332 disposed about a periphery of the upper cover 302. The lower cover 304 can also include a lip 334 that can be opposite the upper cover lip 332 and align with the upper cover lip 332 as shown with respect to FIG. 3. The upper cover lip 332 and the lower cover lip 334 can function to further minimize the penetration of radiation into the housing 328 in addition to the upper housing 302 in combination with the lower housing 304. In particular, upper cover lip 332 and the lower cover lip 334 can function to restrict radiation from any angle, including direct line of sight or any viewing angles.

The radiation shielding assembly 300 is described above as having a rectilinear configuration. The radiation shielding assembly 300 can have any shape that can be dependent on a shape of the electronic component 312. In particular, the electronic component 312 can have a rectilinear configuration as described herein. Thus, the radiation shielding assembly 300 can be localized to the electronic component 312. However, the radiation shielding assembly described herein can have any shape that can complement any shape of an electronic component. Thus, if an electronic component has a triangular shape, a radiation shielding assembly can have a triangular shape such that the radiation shielding assembly can be localized to the triangular electronic component. Furthermore, if an electronic component has a circular shape or any other shape, the radiation shielding assembly can have a circular shape or any other shape the electronic component has, thereby providing localized shielding for the electronic component. By virtue of having an upper cover and a lower cover, the radiation shielding assembly can provide 360° coverage of an electronic component. Moreover, by virtue of having a shape that is similar to the electronic component, mass penalties and footprint penalties on a printed wiring board associated with the radiation shielding assembly are minimized.

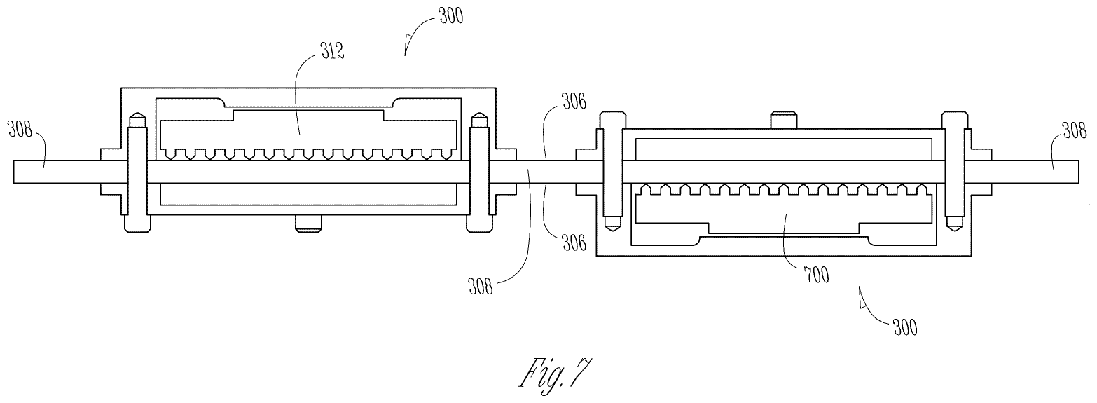

While only a single radiation shielding assembly has been described above, in examples, a printed wiring board can have multiple electronic components where each of the electronic components can have their own radiation shielding assemblies. Making reference to FIG. 7, in addition to the electronic component 312, the printed wiring board 308 can also include an electronic component 700.

The electronic component 700 can also have the radiation shielding assembly 300. Moreover, as shown with respect to FIG. 7, the electronic component 700 can be disposed on the printed wiring board second side 310. While FIG. 7 describes electronic components on opposite sides of the printed wiring board 308, examples envision having electronic components on the same side of a printed wiring board, such as having electronic components on the printed wiring board first side 306 where each of the electronic components have their own radiation shielding assembly 300. In further examples, a single radiation shielding assembly can be configured to house multiple electronic components.

### Additional Examples

Example 1 is an assembly for providing radiation shielding for an electronic component of a spacecraft, the assembly comprising: a printed wiring board, the printed wiring board having a first side and a second side opposite the first side; a radiation shield having a first cover and a second cover opposite the first cover, wherein: the first cover is disposed on the printed wiring board first side, the first cover having a plurality of first cover walls; and the second cover is disposed on the printed wiring board second side, the second cover having a plurality of second cover walls, wherein the plurality of first cover walls define a housing and the plurality of first cover walls have first cover cavities and the plurality of second cover walls have second cover thru passages; wherein the electronic component is disposed on the printed wiring board first side and within the housing, the electronic component defining a perimeter on the printed wiring board, the printed wiring board having passages at the electronic component perimeter, wherein each of the plurality of first cover walls are located at the electronic component perimeter to enclose the electronic component; and a plurality of fasteners where ones of the plurality of fasteners extend through the second cover thru passages and the printed wiring board passages and into the first cover cavities thereby sealing the first cover and the second cover against the printed wiring board.

In Example 2, the subject matter of Example 1 includes, wherein the first cover includes a first cover lip extending about a periphery of the plurality of first cover walls, the first cover lip being disposed at the printed wiring board first side.

In Example 3, the subject matter of Example 2 includes, wherein the second cover includes a second cover lip extending about a periphery of the plurality of second cover walls, the second cover lip being disposed at the printed wiring board second side and aligning with the first cover lip.

In Example 4, the subject matter of Examples 1-3 includes, wherein the plurality of first cover walls and the plurality of second cover walls are formed from any high-density material such as one of copper or plastic.

In Example 5, the subject matter of Examples 1-4 includes, wherein the electronic component has a ball grid array and the electronic component perimeter allows for processing of the ball grid array.

In Example 6, the subject matter of Examples 1-5 includes, wherein each of the plurality of fasteners are threaded fasteners and the first cover cavities include complementary threads for mating with the threaded fasteners.

Example 7 is an assembly for providing radiation shielding for an electronic component of a spacecraft, the assembly comprising: a printed wiring board, the printed wiring board having a first side and a second side opposite the first side; a radiation shield having a first cover and a second cover opposite the first cover, wherein: the first cover is disposed on the printed wiring board first side, the first cover having a plurality of first cover walls; and the second cover is disposed on the printed wiring board second side, the second cover having a plurality of second cover walls, wherein the plurality of first cover walls define a housing and the plurality of first cover walls have first cover cavities and the plurality of second cover walls have second cover thru passages; and wherein the electronic component is disposed on the printed wiring board first side and within the housing, the electronic component defining a perimeter on the printed wiring board, the printed wiring board having passages at the electronic component perimeter, wherein each of the plurality of first cover walls are located at the electronic component perimeter to enclose the electronic component.

In Example 8, the subject matter of Example 7 includes, the assembly further comprising a plurality of fasteners where ones of the plurality of fasteners extend through second cover passages and the printed wiring board passages and into the first cover cavities thereby sealing the first cover and the second cover against the printed wiring board.

In Example 9, the subject matter of Example 8 includes, wherein each of the plurality of fasteners are threaded fasteners and the first cover cavities include threads for mating with the threaded fasteners.

In Example 10, the subject matter of Examples 7-9 includes, wherein the first cover includes a first cover lip extending about a periphery of the plurality of first cover walls, the first cover lip being disposed at the printed wiring board first side.

In Example 11, the subject matter of Example 10 includes, wherein the second cover includes a second cover lip extending about a periphery of the plurality of second cover walls, the second cover lip being disposed at the printed wiring board second side and aligning with the first cover lip.

In Example 12, the subject matter of Examples 7-11 includes, wherein the plurality of first covers walls and the plurality of second cover walls are formed from any high-density material such as one of copper or plastic.

In Example 13, the subject matter of Examples 7-12 includes, wherein the electronic component has a ball grid array and the electronic component perimeter allows for processing of the ball grid array.

Example 14 is an assembly for providing radiation shielding for an electronic component of a spacecraft, the assembly comprising: a radiation shield having a first cover and a second cover opposite the first cover, wherein: the first cover having a plurality of first cover walls; and the second cover having a plurality of second cover walls, wherein the plurality of first cover walls define a housing and the plurality of first cover walls have first cover cavities and the plurality of second cover walls have second cover thru passages; and wherein the electronic component is disposed within the housing, the electronic component defining a perimeter, wherein each of the plurality of first cover walls are located at the electronic component perimeter to enclose the electronic component.

In Example 15, the subject matter of Example 14 includes, the assembly further comprising a printed wiring board having a first side and a second side opposite the first side, wherein: the first cover is disposed on the printed wiring board first side; the second cover is disposed on the printed wiring board second side; and the electronic component is disposed on the printed wiring board first side where the printed wiring board has passages at the electronic component perimeter.

In Example 16, the subject matter of Example 15 includes, the assembly further comprising a plurality of fasteners where ones of the plurality of fasteners extend through second cover thru passages and the printed wiring board passages and into the first cover cavities thereby sealing the first cover and the second cover against the printed wiring board.

In Example 17, the subject matter of Examples 15 and 16 includes, wherein the first cover includes a first cover lip extending about a periphery of the plurality of first cover walls, the first cover lip being disposed at the printed wiring board first side.

In Example 18, the subject matter of Example 17 includes, wherein the second cover includes a second cover lip extending about a periphery of the plurality of second cover walls, the second cover lip being disposed at the printed wiring board second side and aligning with the first cover lip.

In Example 19, the subject matter of Examples 15-18 includes, wherein the plurality of first covers walls and the plurality of second cover walls are formed from any high-density material such as one of copper or plastic.

In Example 20, the subject matter of Examples 15-19 includes, wherein the electronic component has a ball grid array and the electronic component perimeter allows for processing of the ball grid array.

Example 21 is an apparatus comprising means to implement of any of Examples 1-20.

Example 22 is a method to implement of any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. An assembly for providing radiation shielding for an electronic component of a spacecraft, the assembly comprising:
a printed wiring board, the printed wiring board having a first side and a second side opposite the first side;
a radiation shield having a first cover and a second cover opposite the first cover, wherein:
the first cover is disposed on the printed wiring board first side, the first cover having a plurality of first cover walls; and
the second cover is disposed on the printed wiring board second side, the second cover having a plurality of second cover walls, wherein the plurality of first cover walls define a housing and the plurality of first cover walls have first cover cavities and the plurality of second cover walls have second cover thru passages;
wherein the electronic component is disposed on the printed wiring board first side and within the housing, the electronic component defining a perimeter on the printed wiring board, the printed wiring board having passages at the electronic component perimeter, wherein each of the plurality of first cover walls are located at the electronic component perimeter to enclose the electronic component; and
a plurality of fasteners where ones of the plurality of fasteners extend through the second cover thru passages and the printed wiring board passages and into the first cover cavities thereby sealing the first cover and the second cover against the printed wiring board.

2. The assembly of claim 1, wherein the first cover includes a first cover lip extending about a periphery of the plurality of first cover walls, the first cover lip being disposed at the printed wiring board first side.

3. The assembly of claim 2, wherein the second cover includes a second cover lip extending about a periphery of the plurality of second cover walls, the second cover lip being disposed at the printed wiring board second side and aligning with the first cover lip.

4. The assembly of claim 1, wherein the plurality of first cover walls and the plurality of second cover walls are formed from a high-density material.

5. The assembly of claim 1, wherein the electronic component has a ball grid array and the electronic component perimeter allows for processing of the ball grid array.

6. The assembly of claim 1, wherein each of the plurality of fasteners are threaded fasteners and the first cover cavities include complementary threads for mating with the threaded fasteners.

7. An assembly for providing radiation shielding for an electronic component of a spacecraft, the assembly comprising:
a printed wiring board, the printed wiring board having a first side and a second side opposite the first side;
a radiation shield having a first cover and a second cover opposite the first cover, wherein:
the first cover is disposed on the printed wiring board first side, the first cover having a plurality of first cover walls; and
the second cover is disposed on the printed wiring board second side, the second cover having a plurality of second cover walls, wherein the plurality of first cover walls define a housing and the plurality of first cover walls have first cover cavities and the plurality of second cover walls have second cover thru passages; and
wherein the electronic component is disposed on the printed wiring board first side and within the housing, the electronic component defining a perimeter on the printed wiring board, the printed wiring board having passages at the electronic component perimeter, wherein each of the plurality of first cover walls are located at the electronic component perimeter to enclose the electronic component.

8. The assembly of claim 7, the assembly further comprising a plurality of fasteners where ones of the plurality of fasteners extend through second cover passages and the printed wiring board passages and into the first cover cavities thereby sealing the first cover and the second cover against the printed wiring board.

9. The assembly of claim 8, wherein each of the plurality of fasteners are threaded fasteners and the first cover cavities include threads for mating with the threaded fasteners.

10. The assembly of claim 7, wherein the first cover includes a first cover lip extending about a periphery of the plurality of first cover walls, the first cover lip being disposed at the printed wiring board first side.

11. The assembly of claim 10, wherein the second cover includes a second cover lip extending about a periphery of the plurality of second cover walls, the second cover lip being disposed at the printed wiring board second side and aligning with the first cover lip.

12. The assembly of claim 7, wherein the plurality of first covers walls and the plurality of second cover walls are formed from a high-density material.

13. The assembly of claim 7, wherein the electronic component has a ball grid array and the electronic component perimeter allows for processing of the ball grid array.

14. An assembly for providing radiation shielding for an electronic component of a spacecraft, the assembly comprising:
a radiation shield having a first cover and a second cover opposite the first cover, wherein:
the first cover having a plurality of first cover walls; and
the second cover having a plurality of second cover walls, wherein the plurality of first cover walls define a housing and the plurality of first cover walls have first cover cavities and the plurality of second cover walls have second cover thru passages; and
wherein the electronic component is disposed within the housing, the electronic component defining a perimeter, wherein each of the plurality of first cover walls are located at the electronic component perimeter to enclose the electronic component.

15. The assembly of claim 14, the assembly further comprising a printed wiring board having a first side and a second side opposite the first side, wherein:
the first cover is disposed on the printed wiring board first side;
the second cover is disposed on the printed wiring board second side; and
the electronic component is disposed on the printed wiring board first side where the printed wiring board has passages at the electronic component perimeter.

16. The assembly of claim 15, the assembly further comprising a plurality of fasteners where ones of the plurality of fasteners extend through second cover thru passages and the printed wiring board passages and into the first cover cavities thereby sealing the first cover and the second cover against the printed wiring board.

17. The assembly of claim 15, wherein the first cover includes a first cover lip extending about a periphery of the plurality of first cover walls, the first cover lip being disposed at the printed wiring board first side.

18. The assembly of claim 17, wherein the second cover includes a second cover lip extending about a periphery of the plurality of second cover walls, the second cover lip being disposed at the printed wiring board second side and aligning with the first cover lip.

19. The assembly of claim 15, wherein the plurality of first covers walls and the plurality of second cover walls are formed from a high-density material.

20. The assembly of claim 15, wherein the electronic component has a ball grid array and the electronic component perimeter allows for processing of the ball grid array.
